(19) United States
(12) Patent Application Publication
(10) Pub. No.: US 2019/0341320 A1
(43) Pub. Date: Nov. 7, 2019

(54) GLASS BASED ELECTRONICS PACKAGES AND METHODS OF FORMING THEREOF

(71) Applicant: CORNING INCORPORATED, Corning, NY (US)

(72) Inventors: Scott Christopher POLLARD, Big Flats, NY (US); Aric Bruce SHOREY, Pittsford, NY (US)

(73) Assignee: Corning Incorporated, Corning, NY (US)

(21) Appl. No.: 16/319,725

(22) PCT Filed: Aug. 1, 2017
(86) PCT No.: PCT/US2017/044829

§ 371 Date: Jan. 22, 2019

Related U.S. Application Data
(60) Provisional application No. 62/369,402, filed on Aug. 1, 2016.

(51) Int. Cl. H01L 23/15; H01L 21/48; H01L 21/56; H01L 21/683; H01L 23/00

(52) U.S. Cl. CPC H01L 23/15; H01L 21/486; H01L 21/561; H01L 21/568; H01L 24/16; H01L 21/4857; H01L 24/97; H01L 2221/68345; H01L 2224/16225; H01L 21/6835

(57) ABSTRACT

Electronics packages that incorporate components such as glass-based interposer assemblies are disclosed, as well as methods of forming thereof. A method includes bonding a glass-based substrate to a carrier, applying a metallization layer and/or a dielectric layer over the glass-based substrate to obtain a layered structure bonded to the carrier, removing sections of the layered structure such that portions of the layered structure remain on the carrier with a space between each thereof, attaching one or more dies to the portions, dispensing an underfill material between the glass-based substrate and the dies to obtain assemblies bonded to the carrier, encapsulating the assemblies with a polymeric material to obtain encapsulated assemblies, removing the carrier from the encapsulated assemblies to expose a back side of the encapsulated assemblies, and applying second metallization layers and second dielectric layers over the back side of the encapsulated assemblies to form the glass-based structures.

### CROSS-REFERENCE TO RELATED APPLICATIONS

This application claims the benefit of priority under 35 U.S.C. § 119 of U.S. Provisional Application Ser. No. 62/369,402 filed on Aug. 1, 2016 the content of which is relied upon and incorporated herein by reference in its entirety.

### BACKGROUND

### Field

The present specification generally relates to wafer and panel level processing involving glass-based materials as a substrate and, more specifically, to methods of forming electronics packages that include glass-based structures such as interposer assemblies for silicon devices.

### Technical Background

For packaging of silicon devices, particularly devices beyond a 32 nanometer (nm) technology node, new technical solutions may be necessary to overcome interconnect limits imposed on chip performance, power dissipation, and packaging form factor. Design elements such as interposers may be used for 2.5D and 3D integration, which may, for example, provide increased levels of device integration by allowing for tighter processor and memory die pitch, provide decreased line width and spacing that allow for increased bandwidth and greater utilization of the available area, and incorporate through-vias for vertical connections of die stack structures.

Current structures use silicon as interposer material, but the use of glass may be more advantageous over silicon because the glass material properties (such as elastic modulus and coefficient of thermal expansion (CTE)) can be engineered for specific applications and requirements. However, methods of forming electronics packages incorporating glass or glass-ceramic materials have not been fully developed.

Accordingly, a need exists for methods of forming electronics packages that incorporate glass-based substrates in large thin sheets for economy of scale (packing form factor) and height benefits (thinner overall packages).

### SUMMARY

According to one embodiment, a method of forming one or more glass-based structures includes applying at least one of (i) one or more first metallization layers or (ii) one or more first dielectric layers over a glass-based substrate bonded to a carrier to obtain a layered structure bonded to the carrier; removing one or more sections of the layered structure such that a plurality of portions of the layered structure remain on the carrier with a space between each of the plurality of portions; attaching one or more dies to the plurality of portions; dispensing an underfill material between the glass-based substrate and the one or more dies to obtain one or more assemblies bonded to the carrier; and encapsulating the one or more assemblies with a polymeric material to obtain one or more encapsulated assemblies.

In another embodiment, a method of forming one or more glass-based structures includes filling at least one hole in each of a plurality of individual glass-based substrates bonded to a carrier, wherein each of the plurality of individual glass-based substrates comprises one or more holes therethrough; applying at least one of (i) one or more first metallization layers or (ii) one or more first dielectric layers over the plurality of individual glass-based substrates to obtain a plurality of layered structures bonded to the carrier; attaching one or more dies to each of the plurality of layered structures; dispensing an underfill material between the plurality of individual glass-based substrates and the dies to obtain a plurality assemblies bonded to the carrier; and encapsulating the plurality assemblies with a polymeric material to obtain a plurality encapsulated assemblies.

In another embodiment, a method of forming one or more glass-based structures includes applying at least one of (i) one or more first metallization layers or (ii) one or more first dielectric layers over a first side of a glass-based substrate bonded to a carrier to obtain a layered structure, wherein the carrier has at least one opening and the glass-based substrate is positioned over the opening and a second side of the glass-based substrate is adjacent the carrier; attaching one or more dies to the layered structure; dispensing an underfill material between glass-based substrate and the one or more dies to obtain an assembly bonded to the window carrier; and encapsulating the assembly with a polymeric material to obtain an encapsulated assembly.

Additional features and advantages of the methods for forming glass-based structures, such as interposers and interposer assemblies, will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts an illustrative glass-based interposer panel according to one or more embodiments shown and described herein;

FIG. 2 schematically depicts a cross sectional view of an illustrative portion of a glass-based interposer panel taken along line 2-2 of FIG. 1 according to one or more embodiments shown and described herein;

FIG. 3 depicts a flow diagram of an illustrative method of forming a glass-based interposer assembly according to one or more embodiments shown and described herein;

FIG. 4A schematically depicts a cross sectional view of an illustrative structure including a glass-based substrate bonded to a carrier according to one or more embodiments shown and described herein;

FIG. 4B schematically depicts a cross sectional view of the structure of FIG. 4A with filled holes on a front side thereof;

FIG. 4C schematically depicts a cross sectional view of singulated portions of the structure of FIG. 4B;

FIG. 4D schematically depicts a cross sectional view of the structure of FIG. 4C coupled to one or more dies;

FIG. 4E schematically depicts a cross sectional view of an encapsulation of the structure of FIG. 4D;

FIG. 4F schematically depicts a cross sectional view of the structure of FIG. 4E with the carrier removed;

FIG. 4G schematically depicts a cross sectional view of the structure of FIG. 4F having metallization and dielectric layers formed on a backside thereof;

FIG. 4H schematically depicts a cross sectional view of singulated portions of the structure of FIG. 4G;

FIG. 4I schematically depicts a cross sectional view of the structure of FIG. 4H coupled to an organic substrate;

FIG. 5 depicts a flow diagram of an illustrative alternative method of forming a glass-based interposer assembly according to one or more embodiments shown and described herein;

FIG. 6A schematically depicts a cross sectional view of an illustrative structure including a plurality of individual glass-based substrates bonded to a carrier according to one or more embodiments shown and described herein;

FIG. 6B schematically depicts a cross sectional view of the structure of FIG. 6A with filled holes on a front side thereof;

FIG. 6C schematically depicts a cross sectional view of the structure of FIG. 6B coupled to one or more dies;

FIG. 6D schematically depicts a cross sectional view of an encapsulation of the structure of FIG. 6C;

FIG. 6E schematically depicts a cross sectional view of the structure of FIG. 6D with the carrier removed;

FIG. 6F schematically depicts a cross sectional view of the structure of FIG. 6F having metallization and dielectric layers formed on a backside thereof;

FIG. 6G schematically depicts a cross sectional view of singulated portions of the structure of FIG. 6F;

FIG. 6H schematically depicts a cross sectional view of the singulated portions of the structure of FIG. 6G coupled to an organic substrate;

FIG. 7 depicts a flow diagram of an illustrative alternative method of forming a glass-based interposer assembly according to one or more embodiments shown and described herein;

FIG. 8A schematically depicts a cross sectional view of an illustrative structure including a plurality of individual glass-based substrates bonded to a window carrier according to one or more embodiments shown and described herein;

FIG. 8B schematically depicts a cross sectional view of the structure of FIG. 8A with filled holes and metallization on a single side only;

FIG. 8C schematically depicts a cross sectional view of the structure of FIG. 8B with filled holes and double sided metallization;

FIG. 8D schematically depicts a cross sectional view of the structure of FIG. 8C coupled to one or more dies;

FIG. 8E schematically depicts a cross sectional view of an encapsulation of the structure of FIG. 8D;

FIG. 8F schematically depicts a cross sectional view of the structure of FIG. 8E with the window carrier removed;

FIG. 8G schematically depicts a cross sectional view of singulated portions of the structure of FIG. 8F; and

FIG. 8H schematically depicts a cross sectional view of the singulated portions of the structure of FIG. 8G coupled to an organic substrate.

### DETAILED DESCRIPTION

Reference will now be made in detail to various embodiments of electronics packages that incorporate glass-based structures, particularly glass-based interposers and glass-based interposer assemblies, examples of which are illustrated in the accompanying drawings. Whenever possible, the same reference numerals will be used throughout the drawings to refer to the same or like parts.

The term “interposer” generally refers to any structure that extends or completes an electrical connection between two or more electronic devices. The two or more electronic devices may be co-located in a single structure or may be located adjacent to one another in different structures such that the interposer functions as a portion of an interconnect nodule or the like. As such, the interposer may contain one or more active areas in which through-vias and other interconnect conductors (such as, for example, power, ground, and signal conductors) are present and formed. When the interposer is formed with other components, such as dies, underfill materials, encapsulants, and/or the like, the interposer may be referred to as an interposer assembly. Also, the term “interposer” may further include a plurality of interposers, such as an array of interposers or the like.

While the present disclosure generally relates to glass-based interposers and/or glass-based interposer assemblies, this disclosure is not limited to such. For example, the processes disclosed herein may be used to form any electronics package containing a glass-based structure, such as radio frequency (RF) components, microelectromechanical systems (MEMS), sensors, actuators, microelectronic components, and/or the like. Other structures that may be formed using the processes described herein should be understood.

A 2D integrated circuit package (2D IC package) is a single package formed by mounting a plurality of semiconductor wafers, dies, chips, and/or the like, and interconnecting them horizontally to function as a single device or system. A 3D integrated circuit package (3D IC package) or 3 dimensional stack integrated circuit package (3DS IC package) is a single integrated package constructed by vertically stacking separate semiconductor wafers, dies, chips, and/or the like, and interconnecting them to function as a single device or system. Through-via technology may enable the interconnections between the multiple semiconductor wafers, dies, chips, and/or the like and the resulting incorporation of substantial functionality into a small package relative to previous technologies. As will be appreciated, the wafers, dies, chips, and/or the like may be heterogeneous. For example, a 3D integrated circuit (3D IC) may be a single wafer/die/chip having two or more layers of active electronic components integrated vertically and horizontally into a single circuit.

A different multi-die package, which is sometimes referred to as a 2.5D integrated circuit package (2.5D IC package), has recently been developed. In a 2.5D IC package, a plurality of wafers, dies, chips, and/or the like are mounted on an interposer structure. A plurality of dies are placed on a passive interposer which is responsible for the interconnections between the dies, as well as the external I/Os through the use of through-via technology. This design may provide cost benefits and better thermal performance over the 3D IC package. As will be appreciated, each “die” can be a 2D IC package, a 2.5D IC package, a 3D IC, or 3D IC package.

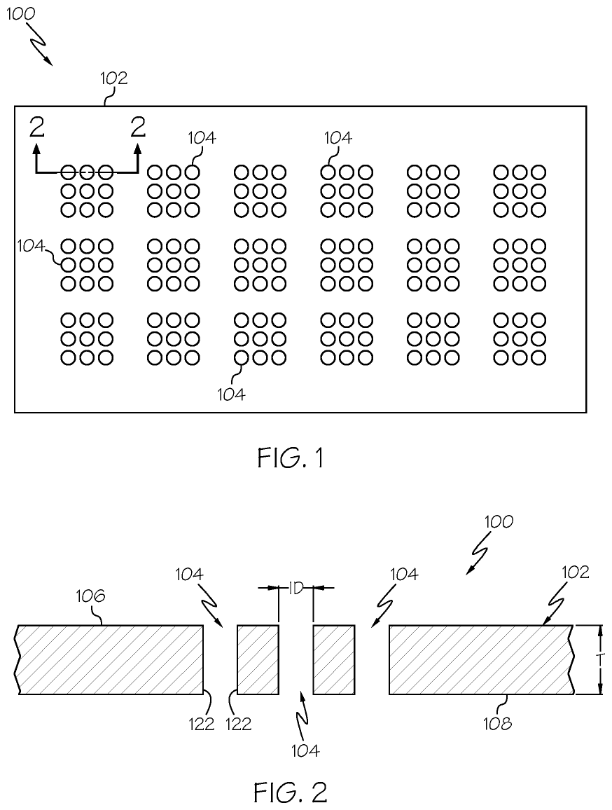

One embodiment of an interposer panel, generally designated 100, is shown in FIG. 1. The glass-based interposer panel 100 (which may also be referred to herein as a glass-based substrate) generally includes a glass-based substrate core 102 in which a plurality of through-vias 104 are formed. As used herein, the term “glass-based” includes both glasses and glass-ceramics. In the embodiments described herein, the glass-based substrate core 102 is formed from a glass composition which may be chemically strengthened, such as by ion exchange processing. For example, the glass substrate core 102 may be formed from soda-lime glass batch compositions, alkali aluminosilicate glass batch compositions, or other glass batch compositions which may be strengthened by ion exchange after formation. In one particular example, the glass substrate core 102 is formed from Gorilla® Glass produced by Corning, Incorporated. In other embodiments, glass-based substrate core 102 may be any suitable glass-ceramic composition or suitable glass composition, for example a borosilicate glass, such as Pyrex® glass.

In various embodiments, the glass-based substrate core 102 is formed from a glass composition that has specified coefficient of thermal expansion (CTE). In some embodiments, the glass substrate core 102 is formed from a glass composition that has a high CTE. For example, the CTE of the glass-based substrate core 102 may be similar to the CTE of circuit materials which may be applied to the glass-based substrate core 102, including, but not limited to, semiconductor materials, metallic materials, and/or the like. In one embodiment, the CTE of the glass-based substrate core 102 may be from about 5×10⁻⁷/° C. to about 100×10⁻⁷/° C. However, it should be understood that the CTE of the glass-based substrate core 102 may be less than about 45×10⁻⁷/° C.

Referring also to FIG. 2, the glass-based substrate core 102 is generally planar, having a first surface 106 and a second surface 108 positioned opposite to and planar with the first surface 106. The glass-based substrate core 102 generally has a thickness T extending between the first surface 106 and the second surface 108. In the embodiments described herein, the thickness T of the glass-based substrate core 102 may be from about 50 microns to about 1 millimeter (mm), including about 50 microns, about 100 microns, about 200 microns, about 300 microns, about 400 microns, about 500 microns, about 600 microns, about 700 microns, about 800 microns, about 900 microns, about 1 mm, or any value or range between any two of these values (including endpoints). For example, in one embodiment, the glass-based substrate core 102 has a thickness T from about 100 microns to about 150 microns. In another embodiment, the glass-based substrate core 102 has a thickness T from about 150 microns to about 500 microns. In yet another embodiment, the glass-based substrate core 102 has a thickness T from about 300 microns to about 700 microns. Other thicknesses of the glass-based substrate core 102 not specifically described herein should be understood.

The glass-based substrate core 102 is initially provided in as-drawn condition (i.e., prior to strengthening by ion exchange) before the through-vias 104 are formed through the thickness T of the glass-based substrate core 102. Thereafter, the through-vias 104 are formed in the un-strengthened glass-based substrate core 102 to create the glass-based interposer panel 100. Forming the through-vias 104 in the un-strengthened glass-based substrate core 102, as described herein, reduces cracking or chipping of the glass-based substrate core 102, particularly in areas adjacent to the through-vias 104 where the glass-based substrate core 102 is susceptible to damage during machining after ion-exchange strengthening.

In various embodiments, the glass-based substrate core 102 may be annealed prior to forming the through-vias 104. Annealing the glass-based substrate core 102 may reduce or eliminate residual stresses present in the glass-based substrate core 102 which may lead to cracking or chipping of the glass-based substrate core 102 during formation of the through-vias 104 when the residual stresses are present in the glass-based substrate core 102 during formation of the through-vias 104. In embodiments where the glass-based substrate core 102 is annealed, the annealing process may include heating the glass-based substrate core 102 to the annealing point of the glass-based material (i.e., to a temperature where the dynamic viscosity of the glass-based material is about 1×10¹³ Poise). However, it should be understood that the annealing step is optional and that, in some embodiments, the through-vias 104 may be formed in the glass-based substrate core 102 without first undergoing an annealing step.

The through-vias 104 may be formed in the un-strengthened glass-based substrate core 102 using any one of a variety of forming techniques. For example, the through-vias 104 may be formed by mechanical drilling, etching, laser ablation, laser assisted processes, laser damage and etching processes, abrasive blasting, abrasive water jet machining, focused electro-thermal energy or any other suitable forming technique.

In various embodiments, the through-vias 104 may have a substantially circular cross section in the plane of the glass-based substrate core 102 and a diameter ID from about 10 microns to about 1 mm, including about 10 microns, about 25 microns, about 50 microns, about 100 microns, about 200 microns, about 300 microns, about 400 microns, about 500 microns, about 600 microns, about 700 microns, about 800 microns, about 900 microns, about 1 mm, or any value or range between any two of these values (including endpoints). In the embodiment shown in FIG. 2, the through-vias 104 have a substantially cylindrical sidewall 122 such that the diameter ID of each through-via 104 is the same at the first surface 106 of the glass-based substrate core 102 and the second surface 108 of the glass-based substrate core 102. However, in other embodiments (not shown), the through-vias 104 may be formed such that they are substantially conical. For example, the through-vias 104 may be formed such that the sidewall 122 of each through-via 103 tapers between the first surface 106 of the glass-based substrate core 102 and the second surface 108 of the glass-based substrate core 102. As such, the through-vias 104 may have a first diameter at the first surface 106 of the glass-based substrate core 102 and a different second diameter at the second surface 108 of the glass-based substrate core 102. In addition, each through-via 104 has approximately the same diameter ID. However, in other embodiments (not shown), the through-vias 104 may be formed with different diameters. For example, a first plurality of through-vias 104 may be formed with a first diameter, while a second plurality of through-vias 104 may be formed with a second diameter.

In another embodiment (not shown), the through-vias 104 may be formed such that the sidewalls 122 of the through-vias 104 taper from the first surface 106 of the glass-based substrate core 102 to a mid-plane of the glass-based substrate core 102 (i.e., a plane through the glass-based substrate core 102 between the first surface 106 of the glass-based substrate core 102 and the second surface 108 of the glass-based substrate core 102) and expand from a mid-plane of the glass-based substrate core 102 to the second surface 108 of the glass-based substrate core 102 (i.e., such that the through-vias 104 have the general shape of an hour glass through the thickness T of the glass-based substrate core 102). In this embodiment, the through-vias 104 may have first diameter at the first surface 106 of the glass-based substrate core 102, a second diameter at the second surface 108 of the glass-based substrate core 102, and a third diameter at a mid-plane of the glass-based substrate core 102 such that the first diameter and the second diameter are greater than the third diameter. In one embodiment, the first diameter and the second diameter may be equal.

While FIG. 2 depicts an embodiment of through-vias 104 with substantially cylindrical sidewalls 122, it should be understood that additional or alternative types of through-vias 104 (e.g., conical or hourglass shaped) may be formed in a single glass-based interposer panel 100. Further, in the embodiment of the glass-based interposer panel 100 depicted in FIG. 1, the through-vias 104 are formed in the un-strengthened glass-based substrate core 102 in a regular pattern. However, it should be understood that, in other embodiments, the through-vias 104 may be formed in a non-regular pattern.

While specific reference has been made herein to through-vias 104 with different cross-sectional geometries through the thickness T of the glass-based substrate core 102, it should be understood that the through-vias 104 may take on a variety of other cross-sectional geometries and, as such, the embodiments described herein are not limited to any particular cross-sectional geometry of the through-vias 104. Moreover, while the through-vias 104 are depicted as having a circular cross section in the plane of the glass-based substrate core 102 in the embodiment of the glass-based interposer panel 100 depicted in FIG. 1, it should be understood that the through-vias 104 may have other planar cross-sectional geometries. For example, the through-vias 104 may have various other cross sectional geometries in the plane of the glass-based substrate core 102, including, without limitation, elliptical cross sections, square cross sections, rectangular cross sections, triangular cross sections, and the like. Further, it should be understood that through-vias 104 with different cross sectional geometries may be formed in a single interposer panel.

In various embodiments, the glass-based interposer panel 100 is formed with a plurality of through-vias 104. However, in other embodiments (not shown), the glass-based interposer panel 100 may also include one or more blind-vias, such as when a via does not extend through the thickness T of the glass-based substrate core 102. In these embodiments, the blind-vias may be formed using the same techniques as the through-vias 104 and may have similar dimensions and planar cross-sectional geometries as the through-vias 104.

In some embodiments, the glass-based interposer panel 100 may be annealed after formation of the through-vias 104. In this embodiment, the annealing step may be utilized to reduce stresses that develop in the glass-based interposer panel 100 during formation of the through-vias 104. For example, where laser-assisted processing is used to form the through-vias 104, thermal stresses may remain in the glass-based substrate core 102 after formation of the through-vias 104. The annealing step may be utilized to relieve these residual stresses such that the glass-based interposer panel 100 is substantially stress-free. However, it should be understood that an annealing step performed after formation of the through-vias 104 is optional and that, in some embodiments, the glass-based interposer panel 100 is not annealed after formation of the through-vias 104.

In another embodiment, the glass-based substrate core 102 may be chemically etched after formation of the through-vias 104. For example, the glass-based substrate core 102 may be chemically etched by submerging the glass-based substrate core 102 in an acid solution which removes defects from the surface of the glass-based substrate core 102 and from the interior of the through-vias 104. Removing these defects by etching reduces the number of crack initiation locations in the glass-based interposer panel 100 and, as a result, improves the strength of the glass-based interposer panel 100. In one embodiment, where the glass-based interposer panel 100 is formed from Gorilla® Glass, the glass-based interposer panel 100 may be chemically etched in a solution of HF:HCl:20H₂O for 15 minutes to remove defects from the surface of the glass-based interposer panels 100 and from the through-vias 104. However, it should be understood that the chemical etching step after formation of the through-vias 104 is optional and that, in some embodiments, the glass-based interposer panel 100 is not chemically etched after formation of the through-vias 104.

After the through-vias 104 have been formed in the glass-based substrate core 102, the glass-based interposer panel 100 is chemically strengthened with an ion exchange process in which smaller metal ions in the glass are replaced or “exchanged” with larger metal ions of the same valence within a layer of the glass that is close to the outer surface of the glass. The replacement of smaller ions with larger ions creates a compressive stress within the surface of the glass which extends to a depth of layer (DOL). In one embodiment, the metal ions are monovalent alkali metal ions (e.g., Na⁺, K⁺, Rb⁺, and the like), and ion exchange is accomplished by immersing the substrate in a bath comprising at least one molten salt (e.g., KNO₃, K₂SO₄, KCl, or the like) of the larger metal ion that is to replace the smaller metal ion in the glass. Alternatively, other monovalent cations such as Ag⁺, Tl⁺, Cu⁺, and the like can be exchanged for the alkali metal cations in the glass. The ion exchange process or processes that are used to strengthen the glass-based interposer panels 100 can include, but are not limited to, immersion of the glass in a single bath or immersion of the glass in multiple baths of like or different compositions with washing and/or annealing steps between immersions.

By way of example, in the embodiments described herein where the glass-based interposer panel 100 is formed from a glass-based substrate core 102 including Gorilla® Glass, the glass-based interposer panel 100 may be ion exchange strengthened by immersing the glass-based substrate core 102 in a KNO₃ molten salt bath having a temperature of about 410° C. When the glass-based substrate core 102 is immersed in the salt bath, Na⁺ ions in the un-strengthened glass-based substrate core 102 are exchanged with K⁻ ions thereby introducing compressive stress in the glass-based substrate core 102. The magnitude and the depth of layer (DOL) of the compressive stress introduced in the glass-based substrate core 102 generally depends on the length of time the glass-based substrate core 102 is immersed in the salt bath. For example, immersing a glass-based substrate core 102 formed from 0.7 mm thick Gorilla® Glass in a KNO₃ salt bath at a temperature of about 410° C. for 7 hours produces a compressive stress of about 720 megapascals (MPa) and a depth of layer of about 50 microns.

While reference has been made herein to a specific ion exchange strengthening process used in conjunction with a specific glass composition, it should be understood that other ion exchange processes may also be used. Moreover, it should be understood that the ion exchange process utilized to strengthen the glass-based interposer panel 100 may vary depending on the specific composition of the glass-based substrate core 102 from which the glass-based interposer panel 100 is formed.

The glass-based interposer panel 100 (or other similar glass-based substrate) described hereinabove with respect to FIGS. 1 and 2 may be used to form electronics packages such as interposer assemblies via a plurality of different methods. As such, an electronics package product may be formed by any one of the processes described herein. In some embodiments, the electronics package products that result from each of the processes described herein may be the same or substantially similar.

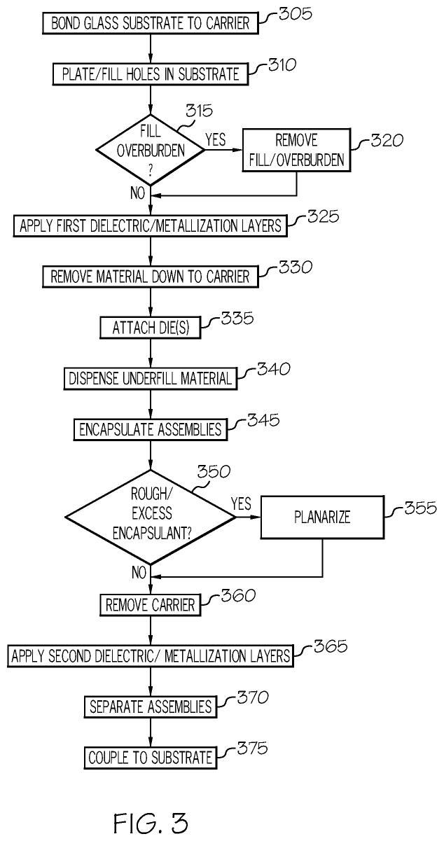

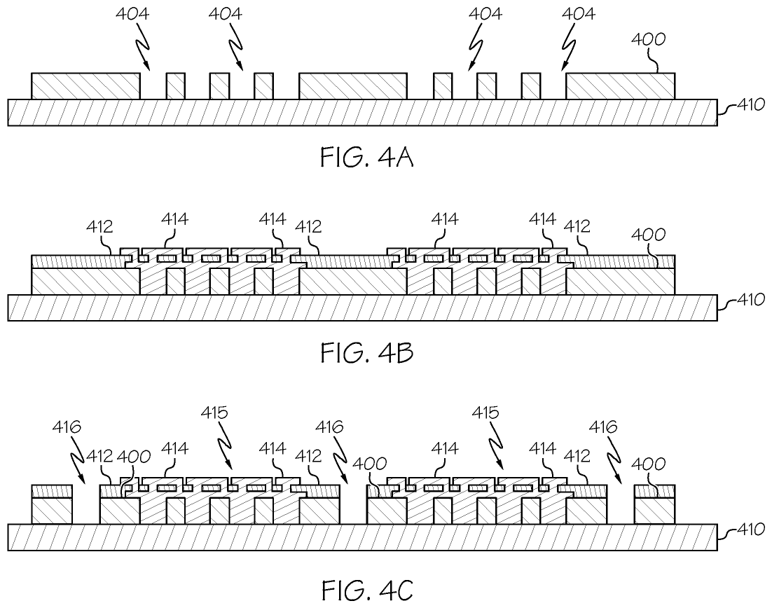

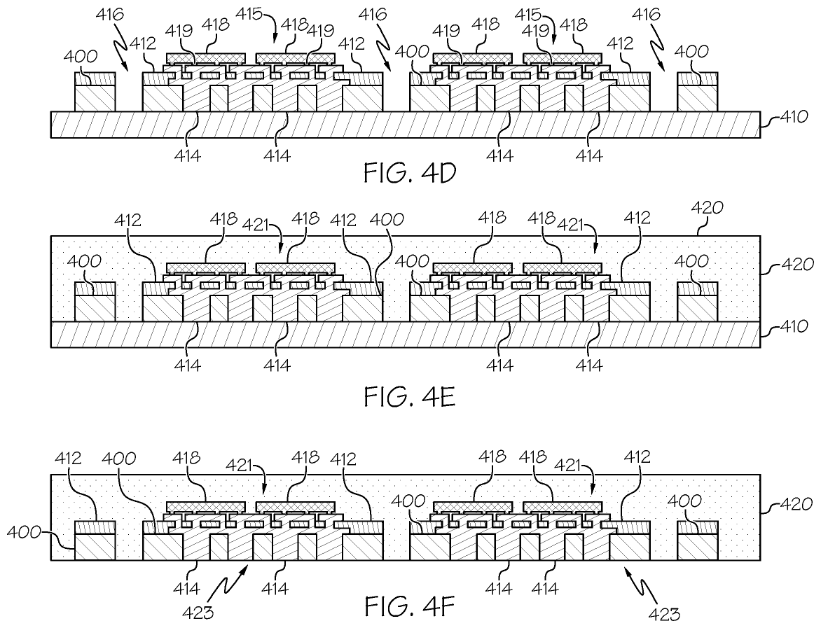

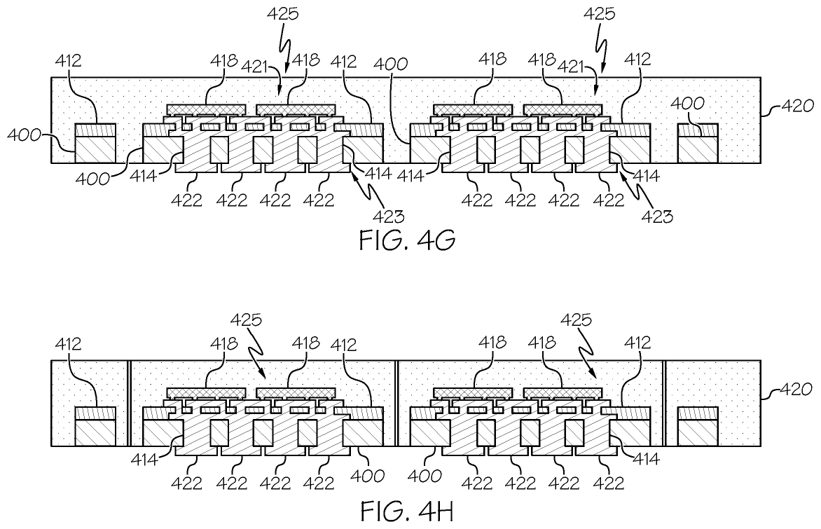

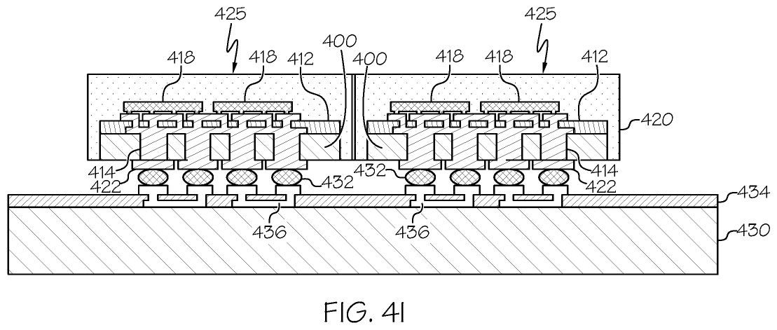

Referring now to FIG. 3, a method of forming an interposer assembly is graphically illustrated. With reference also to FIG. 4A, the method includes bonding a glass-based substrate 400 (e.g., the glass-based interposer panel 100 of FIG. 1) to a carrier 410 at step 305. The carrier 410 is not limited by this disclosure, and may generally be any type of carrier, particularly temporary carriers that are later removed (as described in greater detail herein). Any temporary carrier may be used, particularly temporary carriers that are easily separable from the glass-based substrate 400.

Bonding the glass-based substrate 400 to the carrier 410 according to step 305 may include, for example, temporarily bonding the glass-based substrate 400 to the carrier 410 such that the glass-based substrate 400 can be separated from the carrier 410 at a later point in time, as described in greater detail herein. The glass-based substrate 400 may be bonded to the carrier 410 via any bonding or de-bonding technology now known or later developed. One such nonlimiting illustrative example of a de-bonding technology includes heating and subsequently cooling a surface modification layer that includes a plasma polymerized fluoropolymer or an aromatic silane placed between the glass-based substrate 400 and the carrier 410. Another nonlimiting illustrative example of a de-bonding technology includes depositing a carbonaceous surface modification layer between the glass-based substrate 400 and the carrier 410 and incorporating polar groups with the surface modification layer. Yet another nonlimiting illustrative example of a de-bonding technology includes treating a surface of the glass-based substrate 400 (e.g., the surface that contacts the carrier 410) and/or a surface of the carrier 410 (e.g., the surface that contacts the glass-based substrate 400) with a plasma that contains silicon, oxygen, carbon, and fluorine such that a metal to fluorine ratio of about 1:1 to about 1:3 exists, and contacting the glass-based substrate 400 with the carrier. Other bonding or de-bonding technologies or variations of any of the foregoing may be recognized and are included within the scope of the present disclosure.

As previously described herein, in some embodiments, the glass-based substrate 400 may include one or more holes 404 therethrough, such as, for example, the through-vias 104 as described herein with respect to FIGS. 1 and 2. Referring now to FIGS. 3 and 4A-4B, the one or more holes 404 in the glass-based substrate 400 may be plated and/or filled. As will be described in greater detail herein, the one or more holes 404 may be plated and/or filled with one or more filler materials 414.

Plating the one or more holes 404 may include, for example, conformally plating the one or more holes 404. That is, sidewalls of each of the one or more holes 404 may be coated with at least one of the one or more filler materials 414, but one or more of the holes 404 are not completely filled (i.e., passages remain through the glass-based substrate 400 via the holes 404). As such, conformal plating of the holes occurs when the sidewalls of the holes are coated but are not completely filled.

Filling the one or more holes 404 may include, for example, completely filling the space defined in the glass-based substrate 400 by each of the one or more holes 404 with at least one of the one or more filler materials 414. That is, the one or more holes 404 are entirely filled with at least one of the one or more filler materials 414.

The one or more holes 404 may be plated only, filled only, or plated and filled. For example, in some embodiments, the one or more holes 404 may be plated with a first filler material and filled with a second filler material such that a cross section of the one or more holes 404 contains the first filler material on an outside portion of the one or more holes 404 that completely surrounds the second filler material located on an inside portion of the one or more holes 404.

In embodiments where the one or more holes 404 comprises a plurality of holes, all of the holes 404 may optionally be plated and/or filled in the same manner. That is, each of the plurality of holes 404 contains the same filler material(s) 414 and is plated and/or filled with substantially equal amounts of the one or more filler materials 414 such that the plating and/or filling in each of the plurality of holes 404 is substantially similar. In other embodiments, each individual hole of the plurality of holes 404 may be plated and/or filled in a different manner. For example, a first hole may be conformally plated with a filler material 414, a second hole is filled with the filler material 414, and a third hole is conformally plated and filled with the filler material 414. In yet other embodiments, each individual hole of the plurality of holes may be plated and/or filled with different filler materials 414. For example, a first hole may be conformally plated and/or filled with a first filler material, a second hole may be conformally plated and/or filled with a second filler material, and a third hole may be conformally plated with the first filler material and filled with the second filler material or conformally plated and filled with only the first filler material. Selection of plating and/or filling, as well as the type of filler material may be based on, for example, a particular use or specific configuration of the resultant interposer assembly.

The one or more filler materials 414 are each generally any conductive material and are otherwise not limited by this disclosure. In a nonlimiting example, an illustrative filler material may be copper, a compound containing copper, a redistribution of copper wiring, and/or the like. In another nonlimiting example, an illustrative filler material may include one or more other metals, metal-containing compounds, polymeric materials, and/or the like.

The one or more filler materials 414 may be applied to the one or more holes 404 and/or to a surface of the glass-based substrate 400 via any application method now known or later developed, particularly methods that are generally understood to be suitable for plating and/or filling. For example, the one or more filler materials 414 may be applied via thermal or plasma oxidation or nitridation methods, chemical vapor deposition methods (including atomic layer chemical vapor deposition methods), physical vapor deposition methods (including sputtering methods), and/or the like. As such, the one or more filler materials 414 may be applied in a first state (e.g., a liquid state or molten state) and may be allowed to transition to a second state (e.g., a solid state) after application.

The one or more filler materials 414 may be applied to the one or more holes 404 and/or to a surface of the glass-based substrate 400 in any thickness. As such, the thickness of the resulting layer of one or more filler materials 414 applied to the one or more holes 404 and/or a surface of the glass-based substrate 400 is not limited by this disclosure. The thickness of the resulting layer of one or more filler materials 414 may be consistent over an entire surface of the one or more holes 404 and/or the glass-based substrate 400 or may vary. For example, the thickness of the resulting layer of one or more filler materials 414 in each of the holes 404 may be different. Thicknesses of the resulting layers of the one or more filler materials 414 may be based on particular applications, particular uses, or specific configurations of the resultant interposer assembly.

In some embodiments, a determination may be made at step 315 as to whether excess filler material 414 used for the plating and/or filling of the holes exists. For example, if the filler material 414 is filled to an amount beyond the intended space to be filled (e.g., an excessive amount located on a particular surface of the glass-based substrate 400), the determination may be that an excess amount or overburden exists. If an excess amount or overburden does exist, it may be removed and/or smoothed at step 320. For example, a planarization process may be completed to remove the excess filler material 414 or to smooth the filler material 414 so that it is has a consistent thickness on top of a particular surface of the glass-based substrate 400, contains areas for applying other components and/or materials, and/or the like. Once the excess filler material 414 has been removed and/or smoothed (or if excess filler material 414 does not exist), the process may move to step 325.

In addition to plating and/or filling holes with one or more filler materials 414, the one or more first layers 412 may also be applied over at least a portion of the glass-based substrate 400 and/or in the holes 404 of the glass-based substrate 400.

The one or more first layers 412 generally include one or more metallization materials and/or one or more dielectric materials. For example, in some embodiments, the one or more first layers 412 may include a single metallization material and a single dielectric material. In other embodiments, the one or more first layers 412 may include a plurality of metallization materials and one or more dielectric materials. In yet other embodiments, the one or more first layers 412 may include one or more metallization materials and a plurality of dielectric materials. In yet other embodiments the one or more first layers 412 may include no metallization materials or no dielectric materials.

The metallization materials used for the one or more first layers 412 are not limited by this disclosure. Illustrative metallization materials include, but are not limited to, aluminum, gold, silicon, copper, and tungsten. Similarly, the dielectric materials used for the one or more first layers 412 are not limited by this disclosure. In some embodiments, the dielectric materials may be polymeric materials. Illustrative dielectric materials include, but are not limited to, oxides, nitrides, and oxynitrides of silicon or other elements. Other illustrative examples may include, but are not limited to, laminates and composites of the foregoing oxides, nitrides, and oxynitrides of silicon or other elements. Similarly, the dielectric materials may also be a crystalline material or a non-crystalline material.

The one or more first layers 412 may be formed using any method now known or later developed for applying metallization materials and/or dielectric materials. Nonlimiting examples include thermal or plasma oxidation or nitridation methods, chemical vapor deposition methods (including atomic layer chemical vapor deposition methods), physical vapor deposition methods (including sputtering methods), and/or the like. As such, the one or more first layers 412 may be applied in a first state (e.g., a liquid state or molten state) and may be allowed to transition to a second state (e.g., a solid state) after application.

The resulting one or more first layers 412 applied over the glass-based substrate 400 may each have any thickness. As such, the thickness of the resulting layers is not limited by this disclosure. The thickness of the resulting one or more first layers 412 may be consistent over an entire surface of the glass-based substrate 400 or may vary. Thicknesses of the resulting one or more first layers 412 may be based on particular applications, particular uses, or specific configurations of the resultant interposer assembly.

In embodiments where the holes 404 are filled and/or plated, the one or more first layers 412 may be applied over the filler material 414 and/or in areas surrounding the filler material 414. For example, as particularly shown in FIGS. 4B and 4C, the resulting one or more first layers 412 applied over the glass-based substrate 400 may be located in direct contact with portions of the glass-based substrate and portions of the one or more filler materials 414. That is, where the one or more filler materials 414 extend beyond the cavities defined by the holes 404, the one or more first layers 412 may be dispersed between portions of the filler material 414 on a surface of the glass-based substrate 400 such that portions of the one or more filler materials 414 extend above and below the resulting one or more first layers 412. As a result, the resulting one or more first layers 412 are located between portions of the one or more filler materials 414 and the glass-based substrate 400.

In some embodiments, the one or more first layers 412 may be particularly placed and/or positioned in certain locations with respect to the glass-based substrate 400 and/or other components. For example, the one or more first layers 412 may be placed in locations where contact with other components may be desired, such as at a location so as to be aligned with a die contacting the one or more first layers 412. In another example, the one or more first layers 412 may not be deposited in areas where material may be later removed for splitting components, as described in greater detail herein.

Referring to FIGS. 3 and 4C, certain sections of the various layers of material, including the glass-based substrate 400, the filler material 414, and the one or more first layers 412 may be removed at step 330. That is, all of the material present on the carrier 410 (e.g., a layered structure) is removed in sections down to the carrier 410 to split the remaining material on the carrier 410 (e.g., non-removed material) into discrete portions 415 of the layered structure with one or more channels 416 present between each of the discrete portions 415. As a result, the layered structure is split into the discrete portions 415 while still located on the carrier, as opposed to other processes where a carrier may be removed prior to dividing a substrate into various portions. Splitting the layered structure into the discrete portions 415 may provide an advantage over other methods because it allows for a complete formation of larger panels of electronics assemblies and/or the electronics assemblies are more complete once separated from the panel, thereby reducing the number of steps necessary for further formation. In some embodiments, certain material may not be deposited in areas where the removal occurs to split the remaining material into discrete portions 415. For example, as described herein, the one or more first layers (or a portion thereof) may not be deposited in a general area where the one or more channels 416 are created. As such, removal of the material at this location may not include the one or more first layers 412.

As is shown in FIG. 4C, the carrier 410 itself is not divided into discrete portions; rather the channels 416 only extend through the layered structure, including the glass-based substrate 400, the filler material 414, and the one or more first layers 412. The channels 416 may be formed such that they can accept downstream encapsulant material, as described in greater detail below.

As shown in FIGS. 3 and 4D, at step 335, one or more dies 418 may be attached to the remaining discrete portions 415 of the layered structure. While the term “die” is used herein, it should be understood that any component may be attached to the remaining discrete portions 415 of the layered structure. For example, passive components such as capacitors, resistors, inductors, and/or the like may be attached to the remaining discrete portions 415 of the layered structure. The one or more dies 418 may be attached via any attachment technique now known or later developed, such as, for example, wirebonding, tape automated bonding (TAB), flip-chip soldering, adhesive application, soldering and wirebonding, and/or the like. In flip chip soldering, one or more metal solder bumps are placed between each of the one or more dies 418 and at least a portion of the remaining discrete portions 415, such as, for example, the one or more first layers 412 and/or the filler materials 414. Placement of the bumps may form metallurgical interconnections with the bond sites on each of the one or more dies 418 and the discrete portions 415 (e.g., locations containing the one or more first layers 412). The active side of each of the one or more dies 418 is flipped upside down in order to make contact between the bumps and the metal bond sites on the discrete portions 415.

The number of dies 418 is not limited by this disclosure, and any number of dies may be attached to each of the remaining discrete portions 415 of the layered substrate. For example, as shown in FIG. 4D, two dies 418 are attached to each discrete portion 415. However, in other embodiments, a single die 418 may be attached. In yet other embodiments, greater than two dies 418 may be attached. The number of dies 418 that are attached may be consistent for each discrete portion 415 (e.g., only two dies 418 are attached on each discrete portion 415) or may vary (e.g., one die 418 may be attached to a first discrete portion 415 and two dies 418 may be attached to a second discrete portion 415).

At step 340, underfill material 419 may be dispensed between the discrete portions 415 (or portions thereof, such as the glass-based substrate 400) and the one or more dies 418. The underfill material 419 may be any underfill material that is generally recognized as being used for attaching various integrated circuit components, such as, for example, a polymer, a resin, a curing agent, a fluxing agent, and/or the like. Specific underfill materials 419 may include, but are not limited to, epoxy resins, silicone resins, polyimide resins, benzocyclobutene (BCB), a bismalleimide type underfill, a polybenzoxazine system, or a polynorborene type underfill. Also, the underfill material 419 may optionally be filled with inorganic fillers such as silica to control thermal expansion.

As a result of the die attachment at step 335 and the dispensed underfill at step 340, the resulting structure may be referred to hereinbelow as one or more assemblies bonded to the carrier 410.

Referring now to FIGS. 3, 4E, and 4F, at step 345, the one or more assemblies bonded to the carrier 410 may be encapsulated with an encapsulant 420 to obtain one or more encapsulated assemblies 421. The encapsulant 420 may be applied in a first state (e.g., a liquid or molten state) and allowed to transition to a second state (e.g., a solid state) according to any encapsulation technique now known or later developed. For example, in some embodiments, the encapsulant 420 may be formed by injecting a molding compound into a molding cavity positioned over the one or more assemblies. The encapsulant 420 is not limited by this disclosure and may be comprised of any encapsulating materials, such as, for example, an epoxy molding compound, a resin, a polymeric compound, and/or the like.

In some embodiments, it may be necessary to remove excess amounts of encapsulant 420 from the encapsulated assemblies 421 and/or to smooth the surface of an encapsulated assembly 421. As such, a determination may be made at step 350 as to whether the encapsulated assembly 421 contains one or more rough surfaces and/or if excess encapsulant 420 exists. Such a determination may be based on predetermined dimensional aspects of the encapsulated assemblies 421, predetermined amounts of encapsulant 420 to be applied, and/or the like. If the encapsulated assemblies 421 contain rough surfaces and/or excess encapsulant 420, the encapsulant 420 may be planarized at step 355 according to any planarization process now known or later developed.

Once the encapsulant has been planarized (or if no planarization is necessary), the carrier 410 may be removed from the encapsulated assemblies 421 at step 360, as particularly shown in FIG. 4F. The carrier 410 should generally be removable without relative difficulty and/or without damaging the encapsulated assemblies 421 because of the particular bonding/de-bonding process and/or materials used as described herein. The removal process is not limited by this disclosure, and may generally be any removal process now known or later developed, including removal processes that are specific to the type of bonding/de-bonding method and/or materials used. Nonlimiting examples of removing the carrier 410 may include peeling the carrier 410, heating the carrier 410 to cause the de-bonding material to separate the carrier 410 from the encapsulated assemblies 421, and/or the like. Removing the carrier 410 may generally expose a back side 423 of the one or more encapsulated assemblies 421.

In some embodiments, the carrier 410 may be reused for subsequent electronic package assembly (e.g., additional sheets of interposer assemblies). As such, in some embodiments, removal of the carrier 410 from the encapsulated assemblies 421 may be completed in such a manner so as to not damage the carrier 410. In some embodiments, the removed carrier 410 may be placed in a solution or the like for making reconstituted waste materials, which may include reconstituted waste carriers that are used for subsequent electronic package assembly.

Referring to FIGS. 3 and 4G, at step 365, one or more second layers 422 may be applied to at least a portion of the back side 423 of the one or more encapsulated assemblies 421.

Similar to the one or more first layers 412 described herein, the one or more second layers 422 may include one or more second metallization materials and/or one or more second dielectric materials. For example, in some embodiments, the one or more second layers 422 may include a single metallization material and a single dielectric material. In other embodiments, the one or more second layers 422 may include a plurality of metallization materials and one or more dielectric materials. In yet other embodiments, the one or more second layers 422 may include one or more metallization materials and a plurality of dielectric materials. In yet other embodiments the one or more second layers 422 may include no metallization materials or no dielectric materials.

The metallization materials used for the one or more second layers 422 are not limited by this disclosure. Illustrative metallization materials include, but are not limited to, aluminum, gold, silicon, copper, and tungsten. Similarly, the dielectric materials used for the one or more second layers 422 are not limited by this disclosure. In some embodiments, the dielectric materials may be polymeric materials. Illustrative dielectric materials include, but are not limited to, oxides, nitrides, and oxynitrides of silicon or other elements. Other illustrative examples may include, but are not limited to, laminates and composites of the foregoing oxides, nitrides, and oxynitrides of silicon or other elements. Similarly, the dielectric materials may also be a crystalline material or a non-crystalline material.

The one or more second layers 422 may be formed using any method now known or later developed for applying metallization materials and/or dielectric materials. Nonlimiting examples include thermal or plasma oxidation or nitridation methods, chemical vapor deposition methods (including atomic layer chemical vapor deposition methods), physical vapor deposition methods (including sputtering methods), and/or the like. As such, the one or more second layers 422 may be applied in a first state (e.g., a liquid state or molten state) and may be allowed to transition to a second state (e.g., a solid state) after application.

The resulting one or more second layers 422 applied over the back side 423 of the one or more encapsulated assemblies 421 may each have any thickness. As such, the thickness of the resulting layers is not limited by this disclosure. The thickness of the resulting one or more second layers 422 may be consistent over an entire surface of the back side 423 of the one or more encapsulated assemblies 421 or may vary. Thicknesses of the resulting one or more second layers 422 may be based on particular applications, particular uses, or specific configurations of the resultant interposer assembly.

In embodiments where certain holes located on the back side 423 of the one or more encapsulated assemblies 421 are filled and/or plated, the one or more second layers 422 may be applied over or in the holes.

In some embodiments, the one or more second layers 422 may be particularly placed and/or positioned in certain locations with respect to the glass-based substrate 400 and/or other components. For example, the one or more second layers 422 may be placed in locations where contact with other components may be desired, such as at a location so as to be aligned with an organic substrate or component thereof contacting the one or more second layers 422.

As a result of the application of the one or more second layers 422 on the back side 423 of the one or more encapsulated assemblies 421, one or more glass-based structures 425 are formed.

Referring to FIGS. 3 and 4H, the one or more glass-based structures 425 may be separated from one another at step 370 (e.g., via a singulation process). Separation generally occurs in embodiments where a plurality of glass-based structures 425 are present in an aggregate assembly. If only a single glass-based structure 425 is present, the separation process according to step 370 may be omitted. Separation according to step 370 is not limited by this disclosure, and may be completed via any separation means, such as cutting, for example. Separation of the glass-based structures 425 after encapsulation as described herein may generally ensure that singulation of the glass-based structures 425 does not damage the glass-based substrate 400.

After completion of the foregoing steps, the glass-based structures 425 are ready for application. As such, the glass-based structures 425 may be attached to various other structures, substrates, and/or the like. In some embodiments, as shown in FIGS. 3 and 4I, at least one of the one or more glass-based structures 425 may be coupled to an organic substrate 430 at step 375. Coupling is not limited by this disclosure, and may include, for example, attachment of the organic substrate 430 via one or more bumps 432 placed between the one or more second layers 422 and a portion of the organic substrate 430, such as, for example, one or more contacts 436 on the organic substrate 430. In addition, underfill material 434 may be placed between the organic substrate 430 and the glass-based structures 425.

The organic substrate 430 is not limited by this disclosure and may generally be any organic substrate containing any number of additional components, such as the components described herein. Illustrative examples of materials that may be used for the organic substrate 430 include, but are not limited to, polyethylene, polypropylene, polyether block amide, polyethylene terephthalate, polyetherurethane, polyesterurethane, other polyurethanes, natural rubber, rubber latex, synthetic rubbers, polyester-polyether copolymers, polycarbonates, and other organic materials.

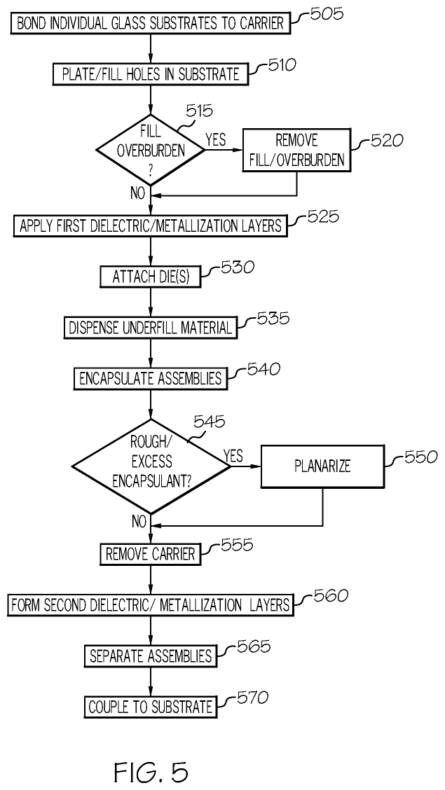

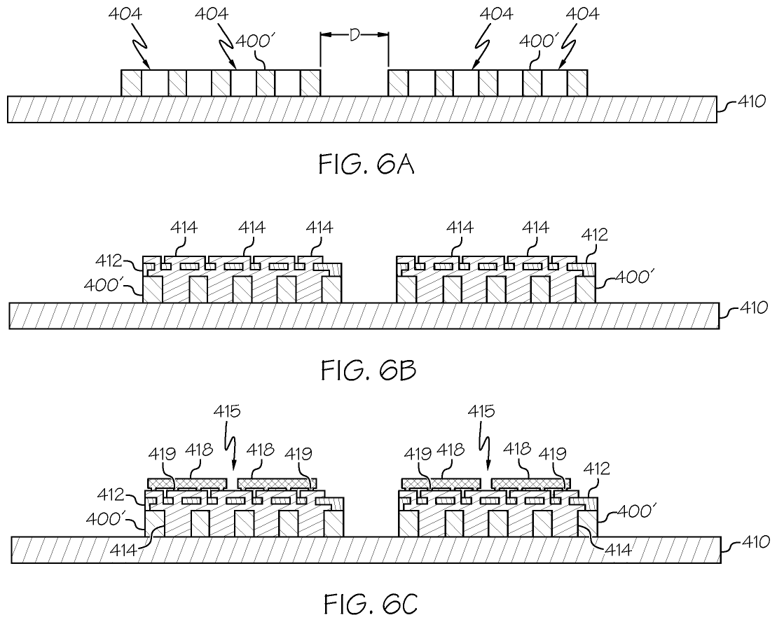

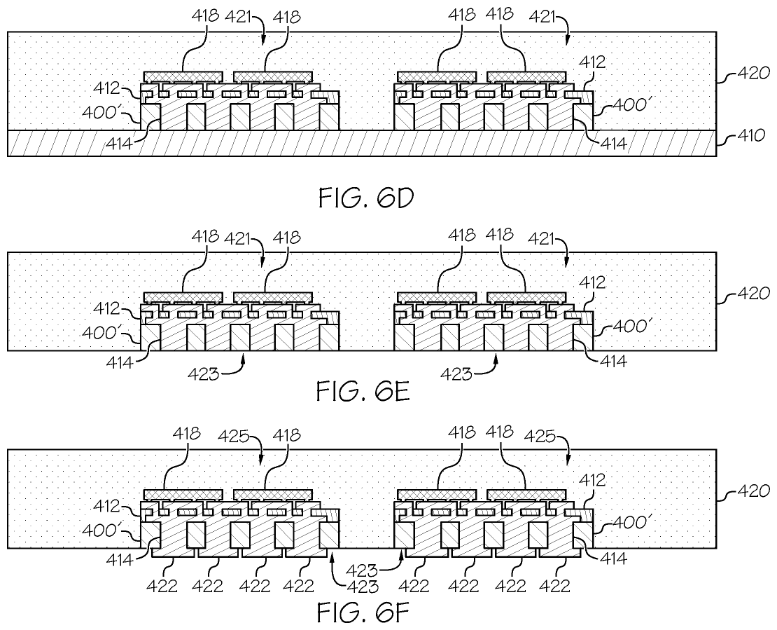

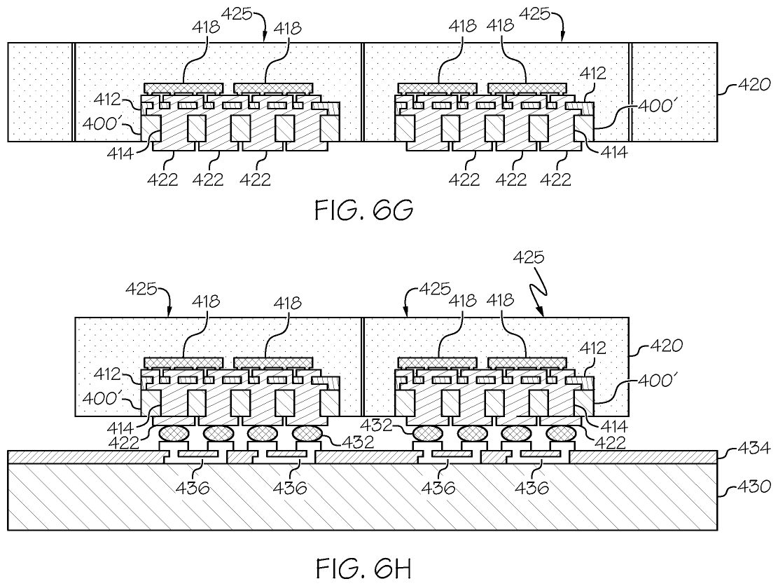

FIG. 5 depicts an alternative method of forming an interposer assembly. A primary difference between the method described with respect to FIG. 5 and the method described with respect to FIG. 3 is that, instead of a single glass-based substrate 400 (FIG. 4A), a plurality of individual substrates 400′ (FIG. 6A) are used, thereby omitting a need to separate the substrate into discrete portions before removal of the carrier. Otherwise, the various other specific details regarding the steps of FIG. 5 are identical to the details regarding the steps of FIG. 3. As such, for the purposes of brevity, the various steps described in FIG. 5 will be briefly described and additional specific details regarding such steps can be found hereinabove with respect to FIG. 3.

Referring now to FIGS. 5 and 6A, the method includes bonding a plurality of glass-based substrates 400′ to a carrier 410 at step 505. As described in greater detail herein, each of the plurality of glass-based substrates 400′ may be a glass-based interposer wafer. The type of glass-based wafer is not limited by this disclosure, and may be any glass-based wafer now known or later developed. In the embodiments described herein, the glass-based wafer may be formed from a glass composition which may be chemically strengthened, such as by ion exchange processing. For example, soda-lime glass batch compositions, alkali aluminosilicate glass batch compositions, or other glass batch compositions which may be strengthened by ion exchange after formation. In one particular example, the glass-based wafer may be formed from Gorilla® Glass produced by Corning, Incorporated. In other embodiments, glass-based wafer may be any suitable glass-ceramic composition or suitable glass composition, for example a borosilicate glass, such as Pyrex® glass.

Bonding the plurality of glass-based substrates 400′ to the carrier 410 according to step 505 may include, for example, temporarily bonding the plurality of glass-based substrate 400′ to the carrier 410 such that the plurality of glass-based substrates 400′ can be removed from the carrier 410 at a later point in time, as described in greater detail herein. The plurality of glass-based substrates 400′ may be bonded to the carrier 410 via any bonding or de-bonding technology now known or later developed.

The plurality of glass-based substrates 400′ may be bonded to the carrier 410 in any pattern, orientation, and/or configuration. In some embodiments, the plurality of glass-based substrates 400′ may be bonded to the carrier 410 in such a manner so as to maximize the number of glass-based substrates 400′ that can fit on a single carrier 410. Each of the plurality of glass-based substrates 400′ may be spaced apart a distance D from one another. The distance D is not limited by this disclosure and may generally be any measurable distance.

As previously described herein, in some embodiments, the plurality of glass-based substrates 400′ may include one or more holes 404 therethrough, such as, for example, the through-vias 104 as described herein with respect to FIGS. 1 and 2. In some embodiments, the plurality of glass-based substrates 400′ may be redrawn glass-based. Redrawn glass-based generally refers to glass-based is formed in large quantities of continuously formed glass-based that is then cut into a plurality of glass-based substrates. Referring now to FIGS. 5 and 6A-6B, the one or more holes 404 in each of the plurality of glass-based substrates 400′ may be plated and/or filled at step 510. As is described in greater detail herein, the one or more holes 404 may be plated and/or filled with one or more filler materials 414.

In some embodiments, a determination may be made at step 515 as to whether excess or overburden filler material 414 used for the plating and/or filling of the holes exists. If an excess amount or overburden does exist, it may be removed and/or smoothed at step 520. Once the excess filler material 414 has been removed (or if excess filler material 414 does not exist), the process may move to step 525.

In addition to plating and/or filling holes with one or more filler materials 414, one or more first layers 412 may also be applied over the plurality of glass-based substrates 400′ and/or in the holes 404 of the plurality of glass-based substrates 400′ at step 525. In some embodiments, the one or more first layers 412 may include a one or more metallization materials and/or one or more dielectric materials, as described in greater detail herein.

As shown in FIGS. 5 and 6C, at step 530, one or more dies 418 may be attached to each discrete portion 415 comprising each one of the plurality of glass-based substrates 400′, the one or more first layers 412, and the filler material 414. The one or more dies 418 may be attached via any attachment technique now known or later developed, such as, for example, wirebonding, tape automated bonding (TAB), flip-chip soldering, adhesive application, soldering and wirebonding, and/or the like, as described in greater detail herein.

At step 535, underfill material 419 may be dispensed between the discrete portions 415 (or portions thereof, such as a glass-based substrate 400′) and the one or more dies 418. As a result of the die attachment at step 530 and the dispensed underfill at step 535, the resulting structure may be referred to herein as one or more assemblies bonded to the carrier 410.

Referring now to FIGS. 5, 6D, and 6E, at step 540, the one or more assemblies bonded to the carrier 410 may be encapsulated with an encapsulant 420 to obtain a plurality of encapsulated assemblies 421, as described in greater detail herein.

In some embodiments, it may be necessary to remove excess amounts of encapsulant 420 from the encapsulated assemblies 421 or to smooth the surface of an encapsulated assembly 421. As such, a determination may be made at step 545 as to whether the encapsulated assemblies 421 contain one or more rough surfaces and/or if excess encapsulant exists, as described in greater detail herein. If the encapsulated assemblies 421 contain rough surfaces and/or excess encapsulant, the encapsulant may be planarized at step 550 according to any planarization process now known or later developed.

Once the encapsulant has been planarized (or if no planarization is necessary), the carrier 410 may be removed from the encapsulated assemblies 421 at step 555, as particularly shown in FIG. 6E. Removing the carrier 410 may generally expose a back side 423 of the one or more encapsulated assemblies 421.

As previously described herein, in some embodiments, the carrier 410 may be reused for subsequent electronic package assembly (e.g., additional sheets of interposer assemblies).

Referring to FIGS. 5 and 6F, at step 560, one or more second layers 422 may be applied to the back side 423 of the plurality of encapsulated assemblies 421. Similar to the one or more first layers 412 described herein, the one or more second layers 422 may include one or more metallization materials and/or one or more dielectric materials, as described in greater detail herein.

As a result of the application of the one or more second layers 422 on the back side 423 of the one or more encapsulated assemblies 421, a plurality of glass-based structures 425 are formed.

Referring to FIGS. 5 and 6G, the one or more glass-based structures 425 may be separated from one another at step 565. Separation according to step 565 is not limited by this disclosure, and may be completed via any separation means, such as cutting, for example.

After completion of the foregoing steps, the glass-based structures 425 are ready for application. As such, the glass-based structures 425 may be attached to various other structures, substrates, and/or the like. In some embodiments, as shown in FIGS. 5 and 6H, at least one of the one or more glass-based structures 425 may be coupled to an organic substrate 430 at step 570. Coupling is not limited by this disclosure, and may include, for example, attachment of the organic substrate 430 via one or more bumps 432 placed between the one or more second layers 422 and a portion of the organic substrate 430, such as, for example, one or more contacts 436 on the organic substrate 430. In addition, underfill material 434 may be placed between the organic substrate 430 and the glass-based structures 425.

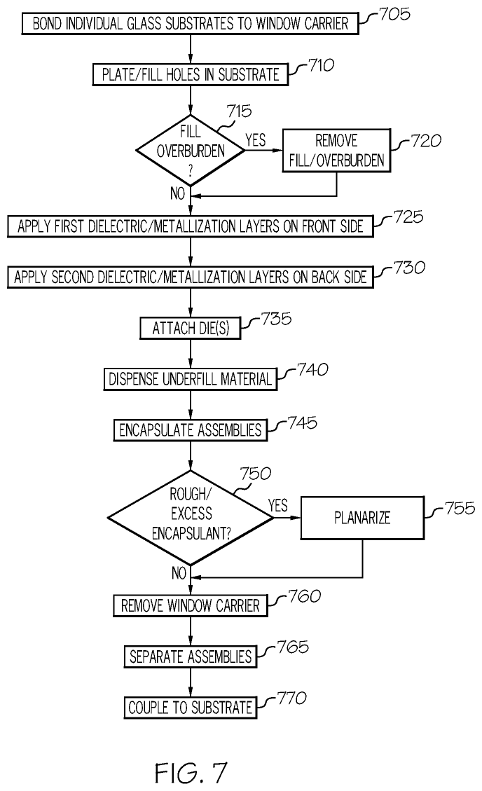

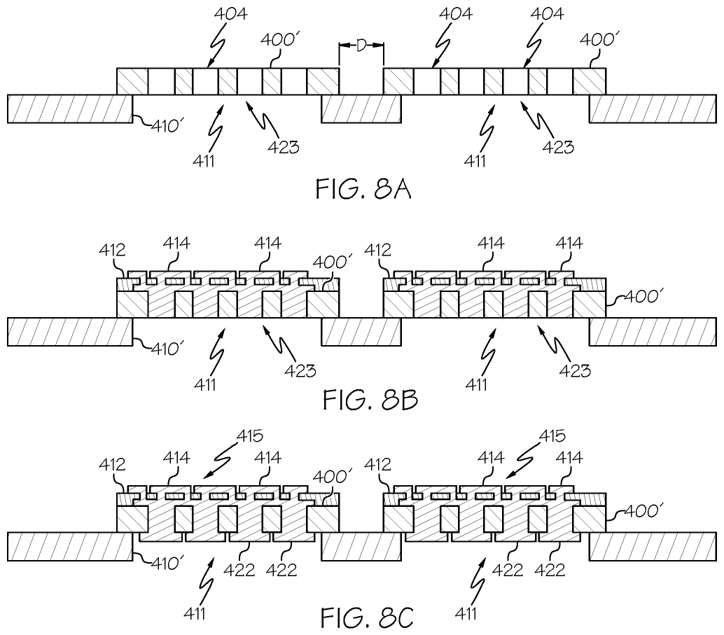

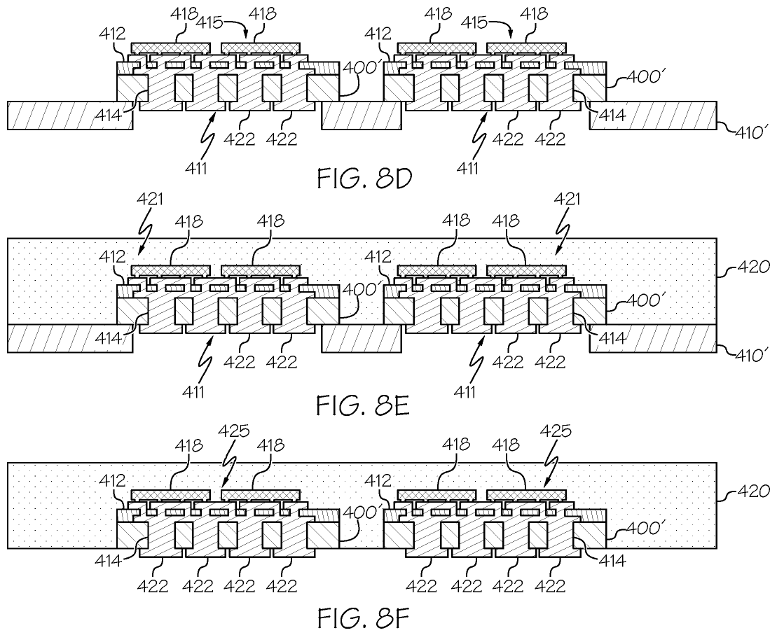

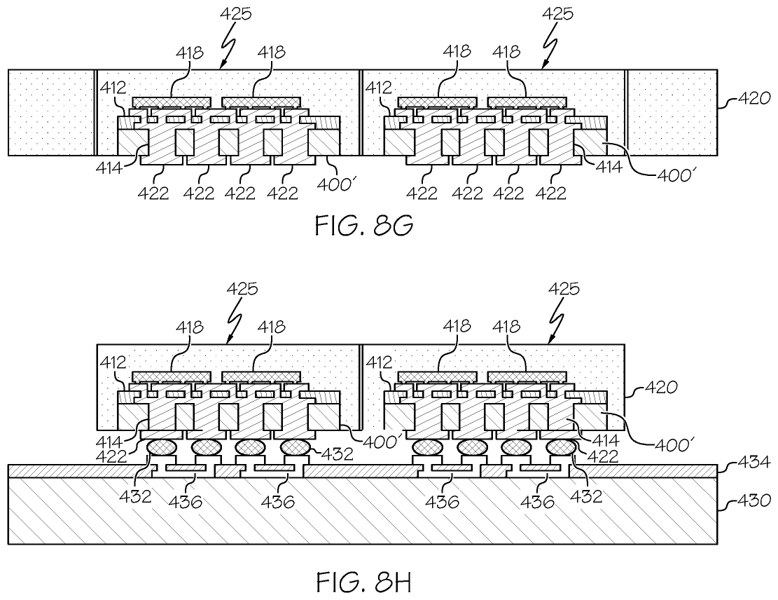

FIG. 7 depicts another alternative method of forming an interposer assembly. A primary difference between the method described with respect to FIG. 7 and the method described with respect to FIG. 3 is that, instead of a single glass-based substrate 400 (FIG. 4A), a plurality of individual substrates 400′ (FIG. 8A) are used, thereby omitting a need to separate the substrate into discrete portions, similar to the method described with respect to FIG. 5. In addition, a primary difference between the method described with respect to FIG. 7 and the method described with respect to FIGS. 3 and 5 is that, instead of a solid carrier 410 (FIGS. 4A and 6A), a window carrier 410′ is used, which allows for double sided filling and layer application steps without a need to flip the various components over to complete a back side filling and layer application. Otherwise, the various other specific details regarding the steps of FIG. 7 are identical to the details regarding the steps of FIGS. 3 and 5. As such, for the purposes of brevity, the various steps described in FIG. 7 that are similar to those described with respect to FIGS. 3 and 5 will be briefly described and additional specific details regarding such steps can be found hereinabove with respect to FIGS. 3 and 5.

Referring now to FIGS. 7 and 8A, the method includes bonding a plurality of glass-based substrates 400′ to a window carrier 410′ at step 705. The window carrier 410′ is not limited by this disclosure, and may generally be any type of carrier that contains one or more openings 411 therethrough (i.e., “windows”) such that at least a portion of a back side 423 of the plurality of glass-based substrates 400′ is accessible through the openings 411 of the window carrier 410′. In addition, the window carrier 410′ is generally a temporary carrier that is later removed (as described in greater detail herein). Any temporary carrier may be used, particularly temporary carriers that are easily removable from the plurality of glass-based substrates 400′.

The openings 411 in the window carrier 410′ are not limited to a particular arrangement, size, and/or shape. However, in some embodiments, each of the openings 411 in the window carrier may be sized, shaped, and/or arranged such that a majority of the back side 423 of a corresponding one of the plurality of glass-based substrates 400′ positioned over the opening 411 is accessible through the opening 411. That is, each of the plurality of glass-based substrates 400′ may be slightly larger than the corresponding opening 411 such that the glass-based substrate 400′ sits overtop the opening 411.

As described in greater detail herein, each of the plurality of glass-based substrates 400′ may be a glass-based interposer wafer. The type of glass-based wafer is not limited by this disclosure, and may be any glass-based wafer now known or later developed. In the embodiments described herein, the glass-based wafer may be formed from a glass composition which may be chemically strengthened, such as by ion exchange processing. For example, soda-lime glass batch compositions, alkali aluminosilicate glass batch compositions, or other glass batch compositions which may be strengthened by ion exchange after formation. In one particular example, the glass-based wafer may be formed from Gorilla® Glass produced by Corning, Incorporated. In other embodiments, glass-based wafer may be any suitable glass-ceramic composition or suitable glass composition, for example a borosilicate glass, such as Pyrex® glass. While FIGS. 7 and 8A-8H depict to a plurality of glass substrates 400′, in some embodiments, a single glass-based substrate (e.g., the glass-based substrate 400 described with respect to FIG. 3) may also be used and subsequently divided into discrete components, as described in greater detail herein.

Bonding the plurality of glass-based substrates 400′ to the window carrier 410′ according to step 705 may include, for example, temporarily bonding the plurality of glass-based substrates 400′ to the window carrier 410′ such that the plurality of glass-based substrates 400′ can be removed from the window carrier 410′ at a later point in time, as described in greater detail herein. The plurality of glass-based substrates 400′ may be bonded to the window carrier 410′ via any bonding or de-bonding technology now known or later developed.

The plurality of glass-based substrates 400′ may be bonded to the window carrier 410′ in any pattern, orientation, and/or configuration. In some embodiments, the plurality of glass-based substrates 400′ may be bonded to the window carrier 410′ in such a manner so as to maximize the number of glass-based substrates 400′ that can fit on a single window carrier 410′. In some embodiments, the plurality of glass-based substrates 400′ may be bonded to the window carrier 410′ such that the back side 423 thereof is accessible through one of the openings 411 in the window carrier 410′, as described herein. Each of the plurality of glass-based substrates 400′ may be spaced apart a distance D from one another. The distance D is not limited by this disclosure and may generally be any measurable distance.

As previously described herein, in some embodiments, the plurality of glass-based substrates 400′ may include one or more holes 404 therethrough, such as, for example, the through-vias 104 as described herein with respect to FIGS. 1 and 2. Referring now to FIGS. 7 and 8A-8B, the one or more holes 404 in each of the plurality of glass-based substrates 400′ may be plated and/or filled at step 710. As is described in greater detail herein, the one or more holes 404 may be plated and/or filled with one or more filler materials 414.

In some embodiments, a determination may be made at step 715 as to whether excess filler material 414 used for the plating and/or filling of the holes exists. For example, if the filler material 414 is filled to an amount beyond the intended space to be filled (e.g., an excessive amount or overburden located on an external surface of one of the one or more glass-based substrates 400′), the determination may be that an excess amount exists. If an excess or overburdne amount does exist, it may be removed and/or smoothed at step 720. Once the excess filler material 414 has been removed (or if excess or overburden filler material 414 does not exist), the process may move to step 725. It should be understood that if any removal/smoothing is completed according to step 720, such removal/smoothing may only occur on a front side of the plurality of glass-based substrates 400′ located on the window carrier 410′ because the presence of the window carrier 410′ prevents removal of material on a back side 423 thereof.

In addition to plating and/or filling holes with one or more filler materials 414, one or more first layers 412 may also be applied over a front side of the plurality of glass-based substrates 400′ and/or in the holes 404 of the plurality of glass-based substrates 400′ at step 725 and one or more second layers 422 may be applied over the back side 423 of the plurality of glass-based substrates 400′ and/or in the holes 404 of the plurality of glass-based substrates 400′ at step 730.

It should generally be understood from the figures that the front side of each of the plurality of glass-based substrates 400′ is opposite the back side 423 thereof, and that the front side and the back side may be coplanar. In addition, the back side is generally adjacent to a surface of the window carrier 410′ as described herein.

As shown in FIGS. 7 and 8C, at step 735, one or more dies 418 may be attached to each discrete portion 415 comprising each one of the plurality of glass-based substrates 400′, the one or more first layers 412, the one or more second layers 422 and the filler material 414, as described in greater detail herein. At step 740, underfill material 419 may be dispensed between the discrete portions 415 (or portions thereof, such as a glass-based substrate 400′) and the one or more dies 418.

As a result of the die attachment at step 735 and the dispensed underfill at step 740, the resulting structure may be referred to herein as one or more assemblies bonded to the window carrier 410′.

Referring now to FIGS. 7 and 8D-8F, at step 745, the one or more assemblies bonded to the window carrier 410′ may be encapsulated with an encapsulant 420 to obtain a plurality of encapsulated assemblies 421.

In some embodiments, it may be necessary to remove excess amounts of encapsulant 420 from the encapsulated assemblies 421 or to smooth the surface of an encapsulated assembly 421. As such, a determination may be made at step 750 as to whether the encapsulated assemblies 421 contain one or more rough surfaces and/or if excess encapsulant exists. If the encapsulated assemblies 421 contain rough surfaces and/or excess encapsulant, the encapsulant may be planarized at step 755 according to any planarization process now known or later developed.

Once the encapsulant has been planarized (or if no planarization is necessary), the window carrier 410′ may be removed from the encapsulated assemblies 421 at step 760, as particularly shown in FIG. 8F. The window carrier 410′ should generally be removable without relative difficulty and/or without damaging the encapsulated assemblies 421 because of the particular bonding/de-bonding process and/or materials used as described herein. The removal process is not limited by this disclosure, and may generally be any removal process now known or later developed, including removal processes that are specific to the type of bonding/de-bonding method and/or materials used. Nonlimiting examples of removing the window carrier 410′ may include peeling the window carrier 410′, heating the window carrier 410′ to cause the de-bonding material to separate, and/or the like.

In some embodiments, the window carrier 410′ may be reused for subsequent electronic package assembly (e.g., additional sheets of interposer assemblies). As such, in some embodiments, removal of the window carrier 410′ from the encapsulated assemblies 421 may be completed in such a manner so as to not damage the window carrier 410′. In some embodiments, the removed window carrier 410′ may be placed in a solution or the like for making reconstituted waste materials, which may include reconstituted waste carriers.

Referring to FIGS. 7 and 8G, the one or more glass-based structures 425 may be separated from one another at step 765. Separation according to step 765 is not limited by this disclosure, and may be completed via any separation means, such as cutting, for example.

After completion of the foregoing steps, the glass-based structures 425 are ready for application. As such, the glass-based structures 425 may be attached to various other structures, substrates, and/or the like. In some embodiments, as shown in FIGS. 7 and 8H, at least one of the plurality of glass-based structures 425 may be coupled to an organic substrate 430 at step 770. Coupling is not limited by this disclosure, and may include, for example, attachment of the organic substrate 430 via one or more bumps 432 placed between the one or more second layers 422 and a portion of the organic substrate 430, such as, for example, one or more contacts 436 on the organic substrate 430. In addition, underfill material 434 may be placed between the organic substrate 430 and the glass-based structures 425.

In various embodiments, an electronics package may be formed by any one of the processes described with respect to FIGS. 3, 5, and 7. The electronics package resulting from any one of the formation processes described herein may be particularly suited for devices beyond 32 nm technology without negatively impacting chip performance, power dissipation, and packaging form factor. The use of glass-based as described herein for the electronics package may result in a package that is smaller in scale and thinner overall relative to conventional electronics packages that use silicon.

It should now be understood that methods of forming electronics packages containing glass-based depicted and described herein include temporarily bonding a glass-based substrate (e.g., a glass-based sheet) or a plurality of glass-based substrates (e.g., a plurality of glass-based wafers) to a carrier. The electronics packages are then formed on top of the carrier, which includes dividing the individual packages from one another (particularly when a glass-based sheet is used) before removing the temporary carrier. As such, the electronics packages can be manufactured in large panel formats using prefabricated glass-based substrates that are in their near-final form. In addition, the methods depicted and described herein allow for glass-based substrate encapsulation, which protects brittle glass-based material from being damaged by mechanical processes such as singulation.

In an aspect (1) a method of forming one or more glass-based structures comprises: applying at least one of (i) one or more first metallization layers or (ii) one or more first dielectric layers over a glass-based substrate bonded to a carrier to obtain a layered structure bonded to the carrier; removing one or more sections of the layered structure such that a plurality of portions of the layered structure remain on the carrier with a space between each of the plurality of portions; attaching one or more dies to the plurality of portions; dispensing an underfill material between the glass-based substrate and the one or more dies to obtain one or more assemblies bonded to the carrier; and encapsulating the one or more assemblies with a polymeric material to obtain one or more encapsulated assemblies.

An aspect (2) according to aspect (1) further comprising: removing the carrier from the one or more encapsulated assemblies to expose a back side of the one or more encapsulated assemblies; and applying at least one of (i) one or more second metallization layers or (ii) one or more second dielectric layers over the back side of the one or more encapsulated assemblies to form the one or more glass-based structures.

An aspect (3) according to aspect (1) or (2), wherein the glass-based substrate is a glass-based wafer or a glass-based panel.

An aspect (4) according to any preceding aspect, further comprising: bonding the glass-based substrate to the carrier; and applying a de-bonding material between the glass-based substrate and the carrier.

An aspect (5) according to any preceding aspect, wherein: the glass-based substrate comprises one or more holes therethrough; and the method further comprises at least one of the following: plating at least one of the one or more holes in the glass-based substrate, and filling at least one of the one or more holes in the glass-based substrate.

An aspect (6) according to aspect (5), further comprising removing excess fill material prior to the applying of the at least one of (i) the one or more first metallization layers or (ii) the one or more first dielectric layers.

An aspect (7) according to any preceding aspect, wherein removing the one or more sections of the layered structure defines the plurality of portions of the layered structure on the carrier and defines one or more channels between the plurality of portions of the layered structure on the carrier.

An aspect (8) according to any preceding aspect, wherein attaching the one or more dies comprises attaching the one or more dies via a flip chip soldering method, an adhesive application method, or a soldering and wirebonding method.

An aspect (9) according to any preceding aspect, further comprising smoothing the polymeric material via a planarization process.

An aspect (10) according to any preceding aspect, wherein: the one or more glass-based structures are an aggregate assembly of a plurality of glass-based structures; and the method further comprises separating each of the plurality of glass-based structures from the aggregate assembly.

An aspect (11) according to any one of aspects (2)-(10), further comprising coupling at least one of the one or more glass-based structures to an organic substrate.

An aspect (12) according to any preceding aspect, wherein the glass-based substrate is glass or glass-ceramic.

In an aspect (13), a method of forming a plurality of glass-based structures comprises: filling at least one hole in each of a plurality of individual glass-based substrates bonded to a carrier, wherein each of the plurality of individual glass-based substrates comprises one or more holes therethrough; applying at least one of (i) one or more first metallization layers or (ii) one or more first dielectric layers over the plurality of individual glass-based substrates to obtain a plurality of layered structures bonded to the carrier; attaching one or more dies to each of the plurality of layered structures; dispensing an underfill material between the plurality of individual glass-based substrates and the dies to obtain a plurality assemblies bonded to the carrier; and encapsulating the plurality assemblies with a polymeric material to obtain a plurality encapsulated assemblies.

An aspect (14) according to aspect (13), further comprising: removing the carrier from the plurality of encapsulated assemblies to expose a back side of the plurality of encapsulated assemblies; and applying at least one of (i) one or more second metallization layers or (ii) one or more second dielectric layers over the back side of the one or more encapsulated assemblies to form the one or more glass-based structures.

An aspect (15) according to aspect (13) or (14), further comprising removing excess fill material prior to the applying of the at least one of (i) the one or more first metallization layers or (ii) the one or more first dielectric layers.

An aspect (16) according to any one of aspects (13)-(15), further comprising smoothing the polymeric material via a planarization process.

An aspect (17) according to any one of aspects (14)-(16), wherein: the plurality of glass-based structures are an aggregate assembly; and the method further comprises separating each of the plurality of glass-based structures from the aggregate assembly.

An aspect (18) according to any one of aspects (14)-(17), further comprising coupling at least one of the plurality of glass-based structures to an organic substrate.

An aspect (19) according to any one of aspects (13)-(18), wherein the individual glass-based substrates are glass or glass-ceramic.

In an aspect (20) a method of forming a glass-based structure comprises: applying at least one of (i) one or more first metallization layers or (ii) one or more first dielectric layers over a first side of a glass-based substrate bonded to a carrier to obtain a layered structure, wherein the carrier has at least one opening and the glass-based substrate is positioned over the opening and a second side of the glass-based substrate is adjacent the carrier; attaching one or more dies to the layered structure; dispensing an underfill material between glass-based substrate and the one or more dies to obtain an assembly bonded to the window carrier; and encapsulating the assembly with a polymeric material to obtain an encapsulated assembly.

An aspect (21) according to an aspect (20), further comprising applying at least one of (i) one or more second metallization layers and (ii) one or more second dielectric layers over the second side of the glass-based substrate to obtain one or more layered structures bonded to the window carrier.

An aspect (22) according to aspect (20) or (21), further comprising removing the window carrier from the encapsulated assembly to form the glass-based structure.

An aspect (23) according to any one of aspects (20)-(22), wherein a plurality of glass-based substrates are bonded to the carrier such that each glass-based substrate is positioned over an opening in the carrier.

An aspect (24) according to any one of aspects (20)-(23), further comprising: at least one of filling one or more holes in the glass-based substrate or plating the one or more holes; and removing excess fill material prior to the applying of the at least one of (i) the one or more first metallization layers or (ii) the one or more first dielectric layers.

An aspect (25) according to any one of aspects (20)-(24), further comprising smoothing the polymeric material via a planarization process.

An aspect (26) according to any one of aspects (22)-(25), further comprising coupling the glass-based structure to an organic substrate.

An aspect (27) according to any one of aspects (20)-(26), wherein the glass-based substrate is glass or glass-ceramic.

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

1. A method of forming one or more glass-based structures, the method comprising:
applying at least one of (i) one or more first metallization layers or (ii) one or more first dielectric layers over a glass-based substrate bonded to a carrier to obtain a layered structure bonded to the carrier;
removing one or more sections of the layered structure such that a plurality of portions of the layered structure remain on the carrier with a space between each of the plurality of portions;
attaching one or more dies to the plurality of portions;
dispensing an underfill material between the glass-based substrate and the one or more dies to obtain one or more assemblies bonded to the carrier; and
encapsulating the one or more assemblies with a polymeric material to obtain one or more encapsulated assemblies.

2. The method of claim 1, further comprising:
removing the carrier from the one or more encapsulated assemblies to expose a back side of the one or more encapsulated assemblies; and
applying at least one of (i) one or more second metallization layers or (ii) one or more second dielectric layers over the back side of the one or more encapsulated assemblies to form the one or more glass-based structures.

3. The method of claim 1, wherein the glass-based substrate is a glass-based wafer or a glass-based panel.

4. The method of claim 1, further comprising:
bonding the glass-based substrate to the carrier; and
applying a de-bonding material between the glass-based substrate and the carrier.

5. The method of claim 1, wherein:
the glass-based substrate comprises one or more holes therethrough; and
the method further comprises at least one of the following:
plating at least one of the one or more holes in the glass-based substrate, and
filling at least one of the one or more holes in the glass-based substrate.

6. The method of claim 5, further comprising removing excess fill material prior to the applying of the at least one of (i) the one or more first metallization layers or (ii) the one or more first dielectric layers.

7. The method of claim 1, wherein removing the one or more sections of the layered structure defines the plurality of portions of the layered structure on the carrier and defines one or more channels between the plurality of portions of the layered structure on the carrier.

8. The method of claim 1, wherein attaching the one or more dies comprises attaching the one or more dies via a flip chip soldering method, an adhesive application method, or a soldering and wirebonding method.

9. The method of claim 1, further comprising smoothing the polymeric material via a planarization process.

10. The method of claim 1, wherein:
the one or more glass-based structures are an aggregate assembly of a plurality of glass-based structures; and
the method further comprises separating each of the plurality of glass-based structures from the aggregate assembly.

11. The method of claim 2, further comprising coupling at least one of the one or more glass-based structures to an organic substrate.

12. The method of claim 1, wherein the glass-based substrate is glass or glass-ceramic.

13. A method of forming a plurality of glass-based structures, the method comprising:
filling at least one hole in each of a plurality of individual glass-based substrates bonded to a carrier, wherein each of the plurality of individual glass-based substrates comprises one or more holes therethrough;
applying at least one of (i) one or more first metallization layers or (ii) one or more first dielectric layers over the plurality of individual glass-based substrates to obtain a plurality of layered structures bonded to the carrier;
attaching one or more dies to each of the plurality of layered structures;
dispensing an underfill material between the plurality of individual glass-based substrates and the dies to obtain a plurality assemblies bonded to the carrier; and
encapsulating the plurality assemblies with a polymeric material to obtain a plurality encapsulated assemblies.

14. The method of claim 13, further comprising:
removing the carrier from the plurality of encapsulated assemblies to expose a back side of the plurality of encapsulated assemblies; and
applying at least one of (i) one or more second metallization layers or (ii) one or more second dielectric layers over the back side of the one or more encapsulated assemblies to form the one or more glass-based structures.

15. The method of claim 13, further comprising removing excess fill material prior to the applying of the at least one of (i) the one or more first metallization layers or (ii) the one or more first dielectric layers.

16. The method of claim 13, further comprising smoothing the polymeric material via a planarization process.

17. The method of claim 14, wherein:
the plurality of glass-based structures are an aggregate assembly; and
the method further comprises separating each of the plurality of glass-based structures from the aggregate assembly.

18. The method of claim 14, further comprising coupling at least one of the plurality of glass-based structures to an organic substrate.

19. The method of claim 13, wherein the individual glass-based substrates are glass or glass-ceramic.

20. A method of forming a glass-based structure, the method comprising:
applying at least one of (i) one or more first metallization layers or (ii) one or more first dielectric layers over a first side of a glass-based substrate bonded to a carrier to obtain a layered structure, wherein the carrier has at least one opening and the glass-based substrate is positioned over the opening and a second side of the glass-based substrate is adjacent the carrier;
attaching one or more dies to the layered structure;
dispensing an underfill material between glass-based substrate and the one or more dies to obtain an assembly bonded to the window carrier; and
encapsulating the assembly with a polymeric material to obtain an encapsulated assembly.

21. The method of claim 20, further comprising applying at least one of (i) one or more second metallization layers and (ii) one or more second dielectric layers over the second side of the glass-based substrate to obtain one or more layered structures bonded to the window carrier.

22. The method of claim 20, further comprising removing the window carrier from the encapsulated assembly to form the glass-based structure.

23. The method of claim 20, wherein a plurality of glass-based substrates are bonded to the carrier such that each glass-based substrate is positioned over an opening in the carrier.

24. The method of claim 20, further comprising:
at least one of filling one or more holes in the glass-based substrate or plating the one or more holes; and
removing excess fill material prior to the applying of the at least one of (i) the one or more first metallization layers or (ii) the one or more first dielectric layers.

25. The method of claim 20, further comprising smoothing the polymeric material via a planarization process.

26. The method of claim 20, further comprising coupling the glass-based structure to an organic substrate.

27. The method of claim 20, wherein the glass-based substrate is glass or glass-ceramic.
